(19) United States
(12) Patent Application Publication
(10) Pub. No.: US 2011/0235413 A1
(43) Pub. Date: Sep. 29, 2011

(54) NONVOLATILE SEMICONDUCTOR MEMORY DEVICE AND METHOD OF CONTROLLING NONVOLATILE SEMICONDUCTOR MEMORY DEVICE

(75) Inventor: Takeshi KAMIGAICHI, Yokohama-shi (JP)

(73) Assignee: Kabushiki Kaisha Toshiba, Tokyo (JP)

(21) Appl. No.: 12/886,847

(22) Filed: Sep. 21, 2010

(30) Foreign Application Priority Data
Mar. 24, 2010 (JP) 2010-068443

(51) Int. Cl. G11C 16/04

(52) U.S. Cl. 365/185.03; 365/185.24

(57) ABSTRACT

A control circuit of a nonvolatile semiconductor memory device according to an embodiment of the present invention sets the lower limit of an intermediate distribution in a page writing operation such that an amount of shift from a first threshold voltage distribution to a second threshold voltage distribution is substantially equal to an amount of shift from the intermediate distribution to a fourth threshold voltage distribution, and raises the lower limit of the intermediate distribution as the number of times writing has been executed increases. When the threshold voltage distribution of a second memory cell adjoining a reading target first memory cell and subject to data write after the first memory cell is the second or fourth threshold voltage distribution, the control circuit executes control of applying a second reading pass voltage higher than the first reading pass voltage to the second memory cell.

### CROSS REFERENCE TO RELATED APPLICATIONS

This application is based on and claims the benefit of priority from prior Japanese Patent Application No. 2010-68443, filed on Mar. 24, 2010, the entire contents of which are incorporated herein by reference.

### FIELD

An embodiment of the present invention relates to a nonvolatile semiconductor memory device and a method of controlling a nonvolatile semiconductor memory device.

### BACKGROUND

### Description of the Related Art

Conventionally, flash memories using memory cells of a type that store charges in a floating gate have often been used as semiconductor memories. This is because flash memories are nonvolatile, cost low per one bit, and are suitable for high integration. Among them, NAND type flash memories can reduce the number of contacts connected to memory cells by connecting a plurality of memory cells in series between select transistors. Therefore, NAND type flash memories are particularly suitable for high integration. There have also appeared memory devices of a multi-value storage type that store data of 2 bits or more per one memory cell. With such devices, it is possible to aim for a further improvement in increasing memory capacity, reducing costs, and reducing space.

However, the recent progress in shrinking of memory cells has reduced the distance between adjoining memory cells. Therefore, when writing is executed to one memory cell, a greater influence of inter-cell interference occurs to the one memory cell to its adjoining memory cell. Various writing schemes and reading schemes have been proposed to reduce the influence of inter-cell interference. For example, the flash memory proposed in JP2009-70501A employs a reading scheme explained below in a data reading operation in order to reduce the influence of inter-cell interference caused by a data writing operation. That is, when executing a reading operation to one selected memory cell, this scheme applies a reading pass voltage different from a normal reading pass voltage Vread to a non-selected memory cell adjoing the selected memory cell.

### BRIEF DESCRIPTION OF THE DRAWINGS

FIG. 1 is a circuit diagram for explaining a memory core configuration of a flash memory according to a first embodiment of the present invention.

FIG. 2 is a diagram showing one example of data writing of four-value data to the flash memory according to the first embodiment.

FIG. 3 is a flowchart showing the procedure of data writing of FIG. 2.

FIG. 4 is a cross section showing capacitance coupling in a memory string of the flash memory according to the first embodiment.

FIG. 5 is a diagram for explaining an inter-cell interference effect in the flash memory according to the first embodiment.

FIG. 6 is a diagram for explaining an inter-cell interference effect in the flash memory according to the first embodiment.

FIG. 7 is a diagram for schematically explaining negative sense of the flash memory according to the first embodiment.

FIG. 8 is a diagram for explaining an inter-cell interference effect in a flash memory according to a second embodiment of the present invention.

FIG. 9 is a diagram for explaining an inter-cell interference effect in a DLA type flash memory.

FIG. 10 is a circuit diagram for explaining the first embodiment applying to a DLA type flash memory.

### DETAILED DESCRIPTION

In a page writing operation, a control circuit of a nonvolatile semiconductor memory device according to an embodiment sets a lower limit of an intermediate distribution such that an amount of shift from a first threshold voltage distribution to a second threshold voltage distribution is substantially equal to an amount of shift from the intermediate distribution to a fourth threshold voltage distribution. The control circuit raises the lower limit of the intermediate distribution as the number of times writing has been executed increases. Further, when the threshold voltage distribution of a second memory cell which adjoins a reading-target first memory cell and which subjects to data write after the first memory cell is written is the second or fourth threshold voltage distribution, the control circuit executes control of applying a second reading pass voltage higher than a first reading pass voltage to the second memory cell.

The nonvolatile semiconductor memory device according to the present embodiment will now be explained in detail with reference to the drawings.

### First Embodiment

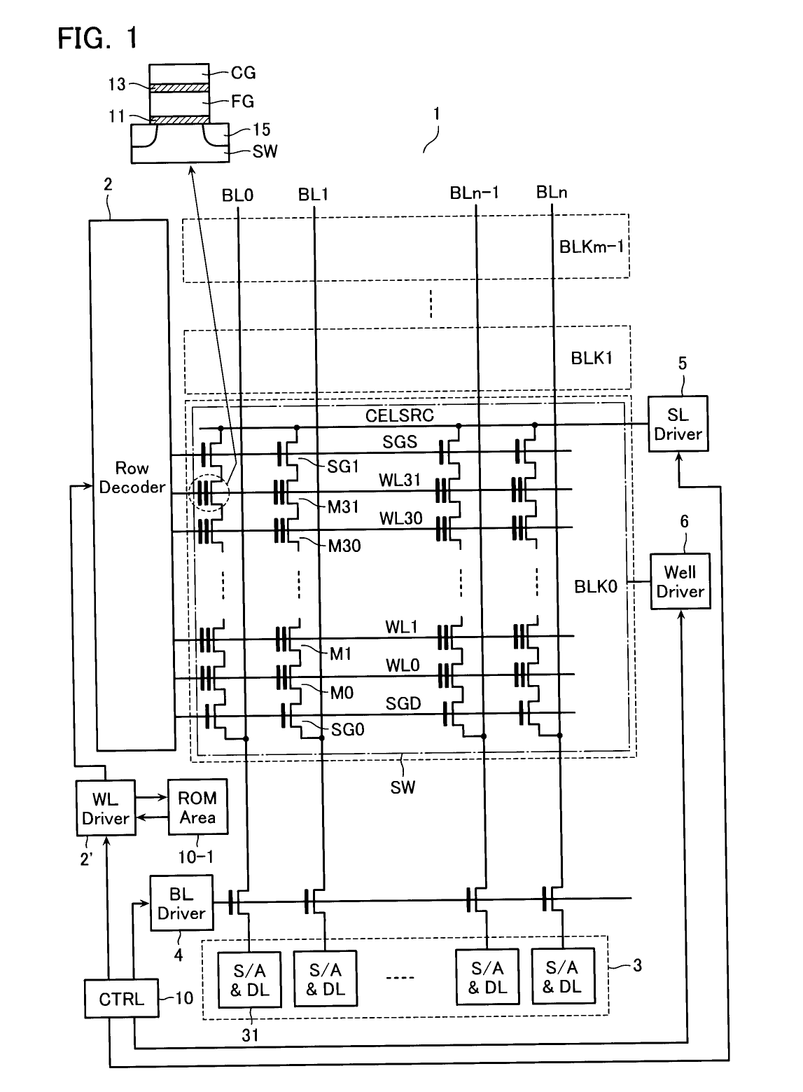

FIG. 1 shows a memory core configuration of a NAND cell type flash memory according to a first embodiment of the present invention.

A memory cell array 1 is configured as an array of NAND strings, each including 32 electrically-rewritable nonvolatile memory cells M0 to M31 connected in series. The number of memory cells in one NAND string is not limited to 32, but may be, for example, 64, 128, etc. Connected to both ends of each NAND string are a drain-side select gate transistor SG0 and a source-side select gate transistor SG1 which become electrically conductive when that NAND string is selected. These 32 memory cells M0 to M31 and the select gate transistors SG0 and SG1 constitute one NAND cell unit.

Each memory cell M may be a floating gate type memory cell which includes: a floating gate (charge accumulation layer) FG formed via a gate insulating film 11 above a p-type well SW formed in a semiconductor substrate; and a control gate CG formed above the floating gate FG via an inter-gate insulating film 13. The plurality of memory cells M connected in series in one NAND string share drain and source diffusion layers 15. Instead of being a floating gate type memory cell, each memory cell M may be a MONOS type memory cell which includes a charge accumulation layer made of, for example, a silicon nitride film or the like.

Each NAND cell unit is connected at one end of the drain side select gate transistor SG0 to a bit line BL and at one end of the source side select gate transistor SG1 to a source line CELSRC.

The control gates of the memory cells M0 to M31 in a NAND cell unit are connected to different word lines WL0 to WL31 respectively. The gates of the select gate transistors SG0 and SG1 are connected to select gate lines SGD and SGS which are parallel with the word lines WL0 to W031.

A row decoder 2 and a word line driver 2′ are provided to select and drive the word lines WL and the select gate lines SGD and SGS. Each bit line BL is connected to a sense amplifier & data latch 31 in a sense amplifier circuit 3. In a reading operation, the bit line BL is charged to a certain voltage (e.g., 1V) by an unillustrated pre-charging circuit included in the sense amplifier & data latch 31. A clamp transistor is connected between the bit line BL and the sense amplifier & data latch 31. The gate voltage of the clamp transistor is controlled by a bit line driver 4.

Here, the bit lines BL are connected in one-to-one correspondence to the sense amplifier & data latches 31. In this case, the memory cells M selected by one word line WL constitute one page to which writing/reading is executed simultaneously. However, for example, an even-number bit line and an odd-number bit line which adjoin each other may share one sense amplifier & data latch. In this case, a half of the memory cells selected by one word line WL constitute a unit of simultaneous writing/reading (one page).

An aggregate of NAND cell units that share word lines constitute a block, which is a unit of data erasing. As illustrated, a plurality of blocks BLK0, BLK1, . . . , and BLKm−1 are arranged along the bit lines BL.

A source line driver 5 and a well driver 6 are provided as circuits that supply voltages to the source line CELSRC and the well SW.

Also provided is a control circuit 10 that controls these drivers 2′, 4, 5, and 6 to control the voltages to be applied to the word lines WL, the bit lines BL, the source line CELSRC, and the well SW.

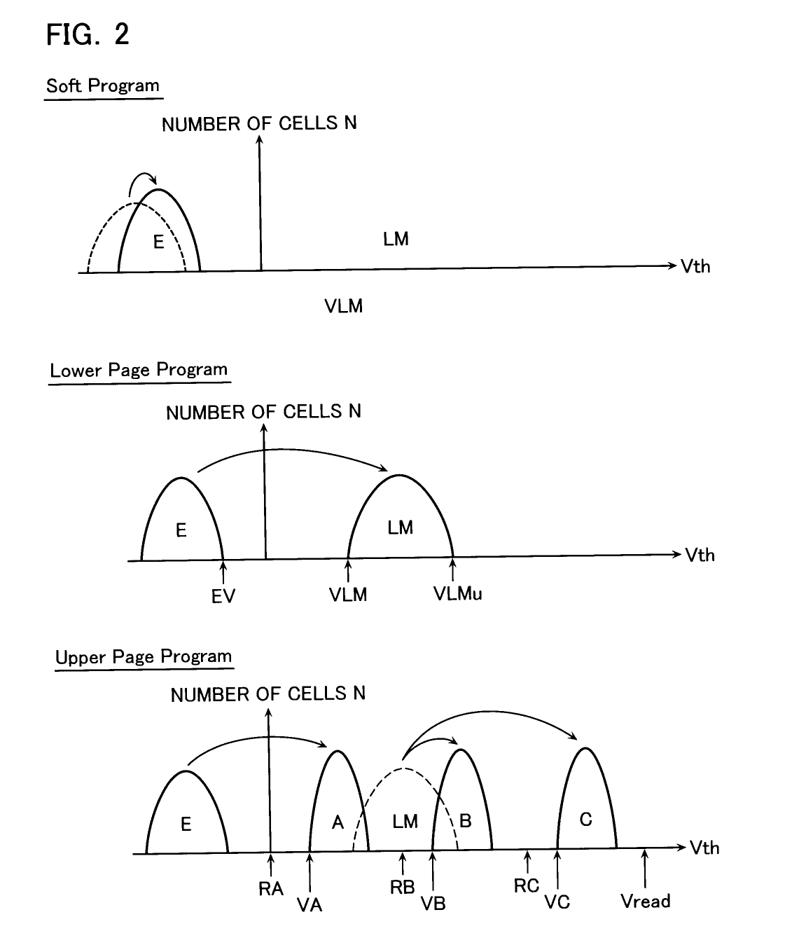

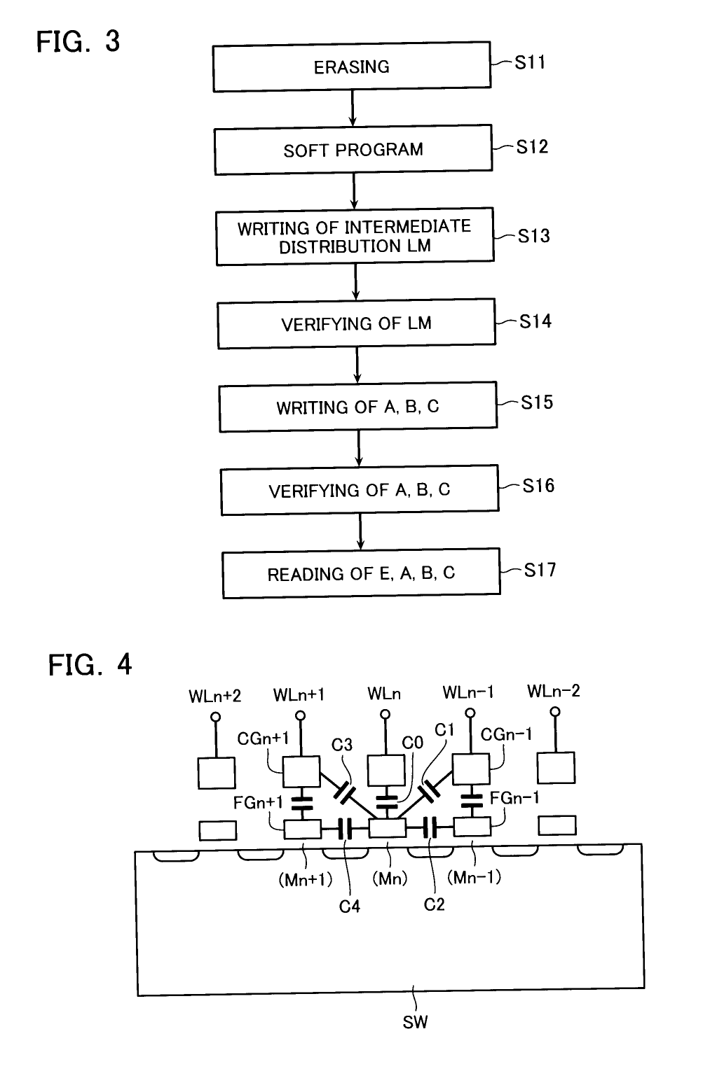

FIG. 2 shows one example of data writing method for executing four-value data storage to the flash memory according to the present embodiment. FIG. 3 is a flowchart showing the procedure for executing this writing method. First to fourth data constituting the four-value data are defined by, for example, a negative threshold voltage distribution E (erased-state distribution: first threshold voltage distribution) having a lowest voltage level, and threshold voltage distributions A (second threshold voltage distribution), B (third threshold voltage distribution), and C (fourth threshold voltage distribution) having higher voltage levels, respectively.

In order to write such four-value data, all the memory cells in a selected block are controlled to have a threshold voltage that is included in the lowest threshold voltage distribution E (data erasing: step S11 of FIG. 3). This data erasing is executed by applying from the well driver 6 a positive erasing voltage to the well SW in which the memory cell array 1 is formed to reset all the word lines WL in the selected block to 0V and discharge electrons from the floating gates FG of all the memory cells M.

As shown in the upper part of FIG. 2, a soft program is executed to all the memory cells in the selected block to shift the threshold voltages of the memory cells M to the positive direction such that the lower limit of the threshold voltage distribution E becomes a certain voltage (step S12 of FIG. 3).

As shown in the middle part of FIG. 2, a lower page program or first page writing is executed to shift part of the memory cells M having the threshold voltage distribution E to an intermediate distribution LM (step S13 of FIG. 3). A verify operation for confirming the completion of the writing of the intermediate distribution LM is executed by setting a verify voltage to a voltage VLM (which is applied across the gate and source of the selected memory cells M) (step S14 of FIG. 3).

As shown in the lower part of FIG. 2, an upper page program or second page writing is executed to shift the threshold voltage distribution from the threshold voltage distribution E to the threshold voltage distribution A or from the intermediate distribution LM to the threshold voltage distribution B or C, and then a verify operation is executed by using a voltage VA, VB or VC as a verify voltage (steps S15 and S16). In this way, writing of all the threshold voltage distributions E to C is completed. After this, a reading operation is executed as needed (step S17). A reading operation is executed by reading simultaneously from the memory cells connected to one control gate. This unit of memory cells read out in one operation is referred to as “page”.

In a reading operation, a reading voltage to be applied across the gate and source of the selected memory cells is set to any one of reading voltages RA, RB, and RC, each of which is a voltage between the upper limit and lower limit of the threshold voltage distributions E to C. On the other hand, a reading pass voltage Vread sufficiently higher than the upper limit of the threshold voltage distribution C is applied to non-selected memory cells.

In the following explanation, the threshold voltage distributions E, A, B, and C, and the intermediate distribution LM may also be referred to simply as E level, A level, B level, C level, and LM level.

The basic data writing/reading operations to the memory cells have been explained. In practice, however, capacitance coupling (inter-cell interference) between the memory cells is considered in the data writing/reading. In particular, if a distance between the memory cells is small, capacitance coupling between the memory cells becomes significant. This becomes the cause of fluctuation of the threshold voltage of the memory cells, as will be explained below.

FIG. 4 is a cross section showing capacitance coupling in a memory string of the flash memory according to the present embodiment. As shown in FIG. 4, the floating gate FG and control gate CG of a memory cell M is coupled to each other by a capacitance C0. The floating gate FGn of a memory cell Mn is coupled to the control gate CGn−1 and floating gate FGn−1 of its adjoining memory cell Mn−1 and to the control gate CGn+1 and floating gate FGn+1 of its adjoining memory cell Mn+1 by capacitances C1, C2, C3, and C4 respectively.

Here, consideration will be given to the fluctuation of the threshold voltage of the memory cells, by employing an example case where the A level will be written into the memory cell Mn and the C level will be written into its adjoining memory cell Mn+1.

In this case, by the lower page program, the memory cell Mn+1 is shifted to the LM level and the memory cell Mn is maintained at the E level.

Then, the memory cell Mn is shifted to the A level by the upper page program to the memory cell Mn.

The memory cell Mn+1 is shifted to the C level by the upper page program to the memory cell Mn+1. At this time, a high writing voltage enough to shift the memory cell Mn+1 from the LM level to the C level is applied to the word line WLn+1. In this case, the threshold voltage of the memory cell Mn is forced to shift to the positive direction due to an inter-cell interference effect which transmits the influence of the writing voltage to the floating gate FG of the memory cell Mn through the capacitances C1 to c4.

In this way, when the C level is written into the adjoining memory cell Mn+1, the threshold voltage of the memory cell Mn largely fluctuates because the amount of shift from the LM level to the C level is large. By the same token, when the A level is written into the adjoining memory cell Mn+1, the threshold voltage of the memory cell Mn also largely fluctuates.

Meanwhile, when the B level is written into the adjoining memory cell Mn+1, the threshold voltage of the memory cell Mn fluctuates less largely than when the A level or the C level is written into the adjoining memory cell Mn+1 because the amount of shift between the LM level and the B level is small. When the adjoining memory cell Mn+1 is maintained at the E level, the threshold voltage of the memory cell Mn also fluctuates less largely. The amount of fluctuation of the threshold voltage of the selected memory cell Mn varies depending on which data is written into the adjoining memory cell Mn+1. In the following explanation, an amount of shift between the threshold voltage distributions will be defined by the distance between the lower limits of the distributions. This is only an example of how to define an amount of shift. For example, an amount of shift can be defined by a difference between the peak values of the distributions. An amount of shift between the threshold voltage distributions is a quantity that fluctuates depending on the space between adjoining memory cells M and the material of an interlayer insulating film that fills the space between the adjoining memory cells M.

Hence, on the premise that the memory cell selected as a data reading target is defined as “selected memory cell” (first memory cell) and the memory cell that adjoins the selected memory cell and that has data written thereinto after the selected memory cell is defined as “adjoining memory cell” (second memory cell), the present embodiment executes the following data reading method.

Before data is read out from the selected memory cell, data is previously read out from the adjoining memory cell in order to apply a reading pass voltage Vdla (second reading pass voltage) higher than a normal reading pass voltage Vread (first reading pass voltage) (Vdla>Vread) to the control gate of the adjoining memory cell in accordance with the read-out data. The reading pass voltage Vread, for example, is applied to the control gates of the other non-selected memory cells. For example, when the writing method shown in FIG. 2 has been executed and the A level or the C level has been written in the adjoining memory cell, the reading pass voltage Vdla is applied to the control gate of the adjoining memory cell. On the other hand, when the E level or the B level has been written in the adjoining memory cell, the reading pass voltage Vread is applied to the control gate of the adjoining memory cell normally. This is because, as shown in FIG. 2, the amount of shift from the E level to the A level and the amount of shift from the LM level to the C level are larger than the amount of shift from the LM level to the B level and such shifts have given a greater influence of inter-cell interference on the selected memory cell. By using the reading pass voltage Vdla instead of the normal reading pass voltage Vread, it is possible to cancel or reduce the influence of inter-cell interference. The reading pass voltage Vdla is higher than the normal reading pass voltage Vread by a correction value α added there to. The correction value α is stored in a ROM area 10-1, and read out by the control circuit 10 in a reading operation.

The reading pass voltage Vdla higher than the normal reading pass voltage Vread comes to be applied to the floating gate of the selected memory cell as well through capacitance coupling occurring between the selected memory cell and the adjoining memory cell. As a result, the threshold voltage of the selected memory cell seemingly shifts to the negative direction. Therefore, the reading operation can substantially reduce the influence of inter-cell interference from the adjoining memory cell occurred in the data writing operation. In other words, the threshold voltage of the selected memory cell has risen in a data writing operation due to inter-cell interference, but seems to lower through the execution of the above reading method. Therefore, the influence of inter-cell interference can be canceled or reduced. This reading method will be referred to as DLA (Direct Look Ahead) method hereinbelow. The DLA method is effective in being able to reduce the influence of inter-cell interference. It is considered what level the voltage Vdla is set. If the voltage Vdla of the same level is used when the data stored in the adjoining memory cell Mn+1 has the A level and when it has the C level.

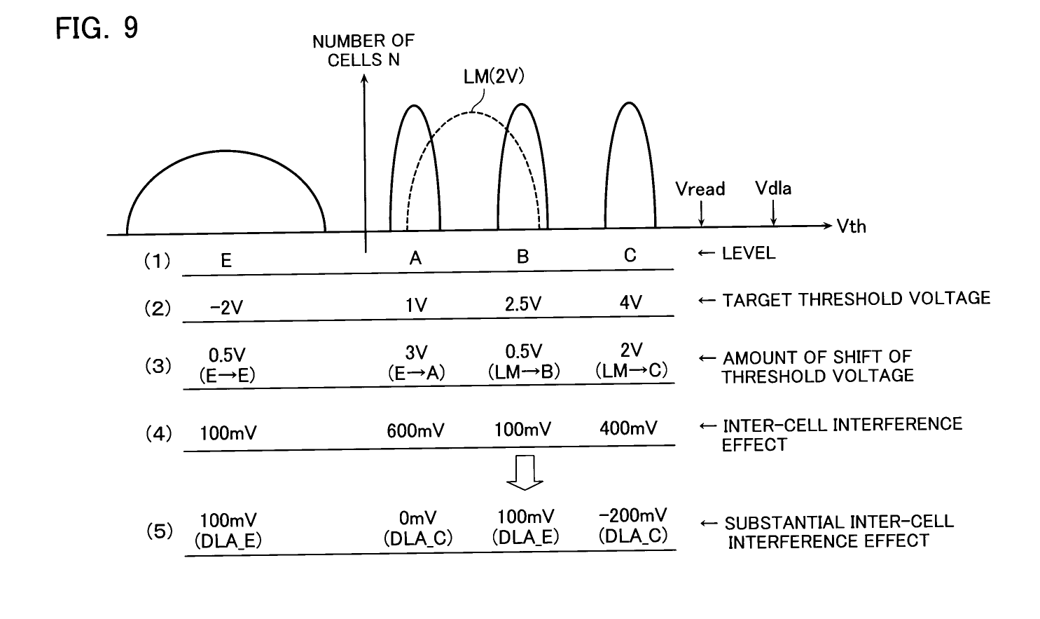

FIG. 9 shows a specific example of an inter-cell interference effect, in connection with the case where the DLA method uses the same reading pass voltage Vdla when the data retained in the adjoining memory cell Mn+1 has the A level and when it has the C level. Here, it is assumed that target threshold voltages (lower limits) of the E level, A level, B level, C level, and LM level are set to −2V, 1V, 2.5V, 4V, and 2V respectively.

When the adjoining memory cell Mn+1 is maintained at the E level by the upper page program, the amount of shift of the threshold voltage of the adjoining memory cell Mn+1 is 0.5V or lower even if the influence of inter-cell interference received from other cells is taken into consideration. When the adjoining memory cell Mn+1 is shifted from the E level to the A level, the amount of shift of the threshold voltage distribution of the adjoining memory cell Mn+1 is about 3V (=1V-(−2V)). When the adjoining memory cell Mn+1 is shifted from the LM level to the B level, the amount of shift of the threshold voltage distribution of the adjoining memory cell Mn+1 is about 0.5V (=2.5V-2V). When the adjoining memory cell Mn+1 is shifted from the LM level to the C level, the amount of shift of the threshold voltage distribution of the adjoining memory cell Mn+1 is about 2V (=4V-2V).

Such shifts of the threshold voltage distribution of the adjoining memory cell Mn+1 cause the threshold voltage distribution of the selected memory cell Mn to shift to the positive direction by about 100 mV (when the adjoining memory cell Mn+1 is maintained at the E level), by 600 mV (when the adjoining memory cell Mn+1 is shifted from the E level to the A level), by 100 mV (when the adjoining memory cell Mn+1 is shifted from the LM level to the B level), and by 400 mV (when the adjoining memory cell Mn+1 is shifted from the LM level to the C level). That is, the selected memory cell Mn receives influence of the inter-cell interference effect from the adjoining memory cell Mn+1. The degree of the inter-cell interference effect varies depending on what data is written in the adjoining memory cell Mn+1. Specifically, when the data written in the adjoining memory cell Mn+1 has the A level or the C level, the inter-cell interference effect given on the selected memory cell Mn is large.

Hence, a conventional DLA type reading method applies a normal reading pass voltage Vread to the control gate of the adjoining memory cell Mn+1 when the data in the adjoining memory cell Mn+1 has the E level or the B level which has a small inter-cell interference effect (“DLA_E” in FIG. 9). On the other hand, the method supplies a reading pass voltage Vdla higher than the reading pass voltage Vread to the control gate of the adjoining memory cell when the data in the adjoining memory cell Mn+1 has the A level or the C level which has a large inter-cell interference effect (“DLA_C” in FIG. 9). By doing so, the method can reduce the influence of the inter-cell interference effect that has been given on the selected memory cell Mn by the upper page program to the adjoining memory cell Mn+1.

As shown in FIG. 9, it is assumed that the same reading pass voltage Vdla is used when the data in the adjoining memory cell Mn+1 has the A level and when it has the C level. If the amount of shift of the threshold voltage distribution when writing is executed to change the data from the E level to the A level is different from the amount of shift of the threshold voltage distribution when writing is executed to change the data from the LM level to the C level, the inter-cell interference effect also becomes different between these cases. Accordingly, using the same reading pass voltage Vdla for both the cases will produce different effects of reducing the inter-cell interference effect. FIG. 9 shows that the inter-cell interference effect is 600 mV in the former case and that it is 400 mV in the latter case. In this situation, if the same reading pass voltage vdla is used in the two cases, the influence of the inter-cell interference effect can be reduced or canceled in one of the cases, but the effect of reducing the inter-cell interference effect might be insufficient or excessive in the other case. FIG. 9 shows that supplying the same reading pass voltage Vdla in both the cases where the data in the adjoining memory cell Mn+1 has the A level and where it has the C level has resulted in that the effect of reducing the inter-cell interference effect is excessive (−200 mV) in the C-level case. This is caused by unbalance between the amount of shift of the threshold voltage distribution when the adjoining memory cell is shifted from the E level to the A level and that when the adjoining memory cell is shifted from the LM level to the C level (the amount of shift of the threshold voltage distribution is 3V in the former case and 2V in the latter case). Due to the recent advancement of shrinking of the memory cells, the voltage value of the E level has lowered. Therefore, the amount of shift of the threshold voltage distribution when writing is executed from the E level to the A level has become larger than the amount of shift of the threshold voltage distribution when writing is executed from the LM level to the C level. The unbalance between these amounts of shift will further increase as the E level shifts to the negative direction along with advanced shrinking of the memory cells. It is also conceivable to use different reading pass voltages Vdla_A and Vdla_C when the data in the adjoining memory cell Mn+1 has the A level and when it has the C level. However, if reading pass voltages are set for the respective data in this way, the control circuit 10 will have to use three kinds of correction values a for reading one page (it should be considered that the reading pass voltage Vread to be used when the data in the adjoining memory cell Mn+1 has other than the A level and the C level includes a correction value α′=0V).

Since a reading operation is executed on a page basis, there exist the same number of adjoining memory cells as the number of bit lines on the word line WLn+1 connected to the adjoining memory cell. These adjoining memory cells store data of E to C levels randomly. That is, the DLA method has to execute the same number of times as the number of kinds of the correction values in order to read one page. If the number of kinds of the correction values increases, the time taken by the control circuit 10 to execute reading will greatly increase, leading to slowdown of the reading speed.

Hence, the flash memory according to the present embodiment controls the target threshold voltage (lower limit) of the LM level such that the amount of shift of the threshold voltage distribution when the adjoining memory cell is shifted from the E level to the A level is substantially the same as the amount of shift of the threshold voltage distribution when the adjoining memory cell is shifted from the LM level to the C level.

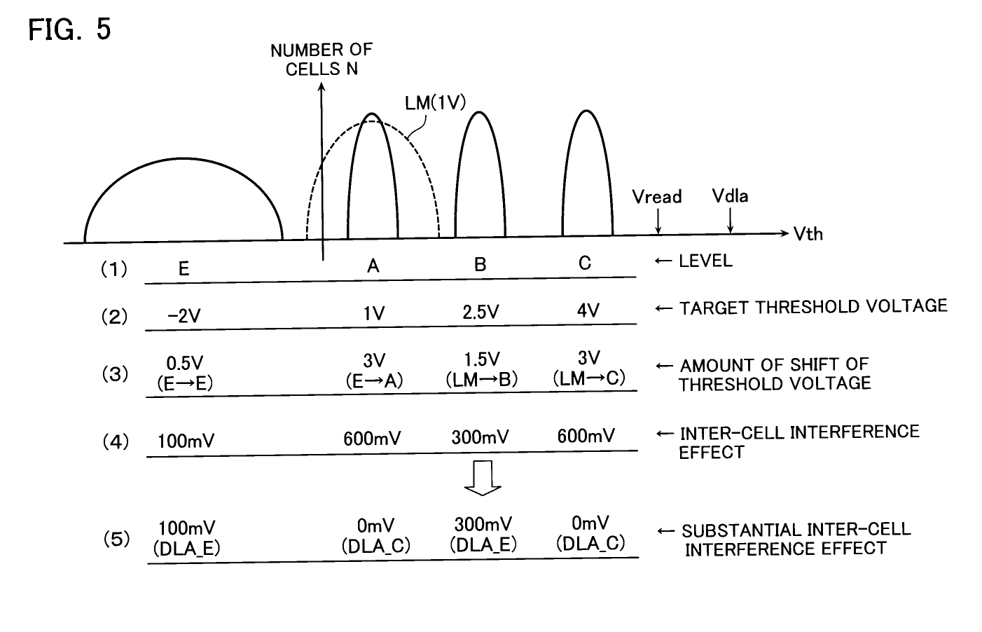

FIG. 5 is a schematic diagram for explaining an inter-cell interference effect in the present embodiment. In the case of the present embodiment, the target threshold voltage of the LM level is controlled to 1V, unlike in the case shown in FIG. 9. Setting the LM level to this level makes the amount of shift of the threshold voltage distribution when the adjoining memory cell is shifted from the E level to the A level be substantially the same as the amount of shift of the threshold voltage distribution when the adjoining memory cell is shifted from the LM level to the C level.

In the present embodiment, the control circuit 10 reads out one-page data by applying any of reading voltages each having a voltage value between adjoining two of the E level to the C level to the word line WLn connected to the reading target selected memory cells Mn among the plurality of memory cells M while applying a reading pass voltage Vread higher than the upper limit of the threshold of the C level to the word lines WL connected to the non-selected memory cells M.

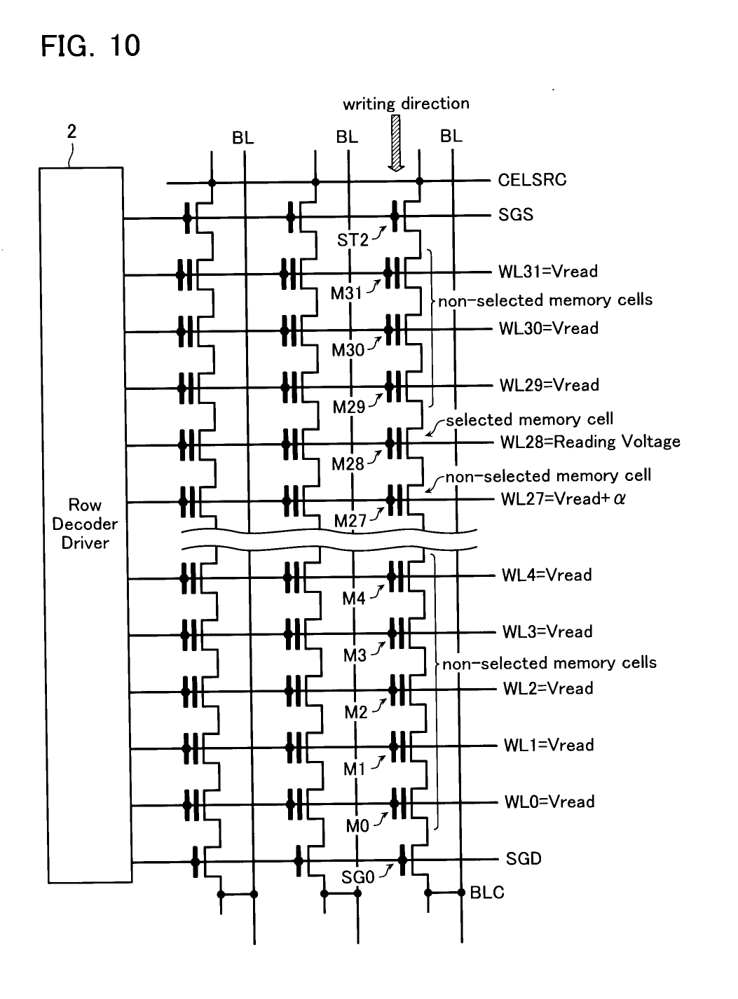

FIG. 10 is a circuit diagram for explaining the first embodiment applying to a DLA type flash memory. Now, memory cells M are written from a select gate line SGS to a select gate line SGD in order (“writing direction” in FIG. 10). At this time, a memory cell M28 is selected in the reading operation. Then, a memory cell M27 is an adjoining memory cell, and memory cells M31-M29 and M27-M0 are a non-selected memory cells. In this case, one of the reading voltages RA, RB or RC is applied to a word line WL28, the reading pass voltage Vdla (=Vread+α) is applied to a word line WL27, and the reading pass voltage Vread is applied to other word lines (WL31-WL29 and WL26-WL0).

In this reading operation, when the threshold voltage distribution of the adjoining memory cell that adjoins the selected memory cell Mn is the threshold voltage distribution of the A level or the C level, the control circuit 10 executes first control of applying a voltage Vdla obtained by adding the correction value α to the reading pass voltage Vread to the word line WL connected to the adjoining memory cell. On the other hand, when the threshold voltage distribution of the adjoining memory cell that adjoins the selected memory cell Mn is the threshold voltage distribution of the E level or the B level, the control circuit 10 executes second control of applying the reading pass voltage Vread to the word line WL connected to the adjoining memory cell without adding the correction value α to the reading pass voltage Vread.

Further, when writing the LM level, the control circuit 10 controls the lower limit of the LM level such that the amount of shift from the E level to the A level is substantially the same as the amount of shift from the LM level to the C level will become approximately the same.

In the case of FIG. 5, when the upper page program is executed to maintain the adjoining memory cell Mn+1 at the E level, the amount of shift of the threshold voltage distribution of the adjoining memory cell Mn+1 is 0.5V. When the upper page program is executed to shift it from the E level to the A level, the amount of shift of the threshold voltage distribution is 3V. When the upper page program is executed to shift it from the LM level to the B level, the amount of shift of the threshold voltage distribution is 1.5V. When the upper page program is executed to shift it from the LM level to the C level, the amount of shift of the threshold voltage distribution is 3V. In these cases, the threshold voltage distribution of the selected memory cell Mn shifts to the positive direction by, for example, 100 mV, 600 mV, 300 mV, or 600 mV respectively, due to the inter-cell interference effect given by the adjoining memory cell Mn+1. Hence, when the adjoining memory cell Mn+1 has the A level and when it has the C level, it is possible to produce the same degree of effect of reducing the inter-cell interference given on the selected memory cell.

As a result, it is possible to reduce the substantial inter-cell interference effect to 0V when the adjoining memory cell has the A level as well as when it has the C level, by applying the same reading pass voltage Vdla. In the case shown in FIG. 5, the correction value α is set to 600 mV. That is, it is possible to share the correction value α between when the data in the adjoining memory cell Mn+1 has the A level and when it has the C level. As a result, it is possible to reduce the substantial inter-cell interference effect to 0V without complicating the operation of the circuit.

In addition to setting the lower limit of the LM level in this way, it is preferable to move (raise) the lower limit of the LM level to the positive direction as the number of times a writing operation or an erasing operation has been executed increases. Repeating data writing/erasing to the memory cells causes deterioration of the tunnel insulating film, which makes the E level gradually shift to the positive direction. Therefore, if the target threshold voltage of the LM level is fixed at a constant value initially set (e.g., 1V as described above), the amount of shift from the E level to the A level will eventually become smaller than and unbalanced against the amount of shift from the LM level to the C level. As a result, in at least one of the cases where the adjoining memory cell has the A level and where it has the C level, appropriate data reading will be unavailable with excessive or insufficient compensation.

Hence, the present embodiment shifts the target threshold voltage of the LM level to the positive direction in accordance with the number of times a writing operation/erasing operation has been executed. That is, it controls the amount of shift from the E level to the A level to be substantially the same as the amount of shift from the LM level to the C level, regardless of the number of times a writing operation/erasing operation has been executed.

In the present embodiment, when writing the LM level, the control circuit 10 controls the lower limit of the LM level such that the amount of shift from the E level to the A level is substantially the same as the amount of shift from the LM level to the C level. Further, the control circuit 10 executes control of raising the lower limit of the LM level as the number of times a writing operation/erasing operation has been executed increases.

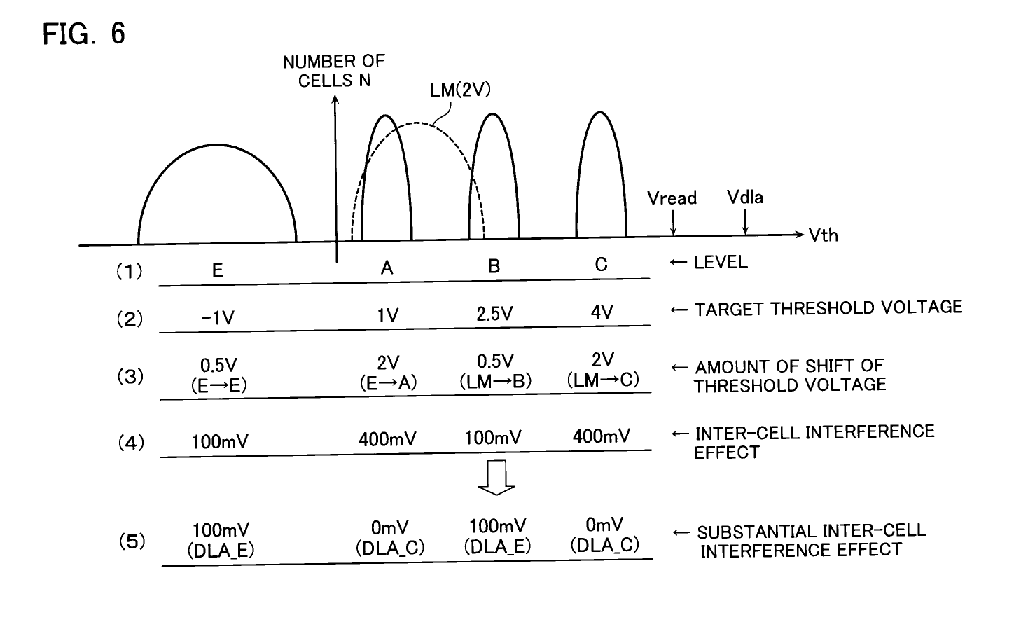

FIG. 6 is a schematic diagram for explaining an inter-cell interference effect after the E level has shifted to the positive direction due to repetitive data writing/erasing. Here, FIG. 6 shows a case where the level E has shifted from the initial level of −2V (see FIG. 5) to −1V.

In this case, the lower limit of the LM level is raised from the initial level of 1V (see FIG. 5) to 2V. Therefore, when the upper page program is executed to the adjoining memory cell Mn+1 to maintain the threshold voltage of the adjoining memory cell Mn+1 at the E level, the amount of shift of the threshold voltage distribution is 0.5V. When the upper page program is executed to shift it from the E level to the A level, the amount of shift of the threshold voltage distribution is 2V. When the upper page program is executed to shift it from the LM level to the B level, the amount of shift of the threshold voltage distribution is 0.5V. When the upper page program is executed to shift it from the LM level to the C level, the amount of shift of the threshold voltage distribution is 2V. As a result, in these cases, the threshold voltage distribution of the selected memory cell Mn shifts to the positive direction by, for example, 100 mV, 400 mV, 100 mV, or 400 mV respectively, due to the inter-cell interference effect caused by the upper page program to the adjoining memory cell Mn+1. Therefore, even when the E level has risen to −1V, raising the LM level to 2V in accordance with the number of times a writing operation/erasing operation has been executed. That is, it is possible to make the inter-cell interference effect that occurs when the adjoining memory cell has the A level be substantially the same as the inter-cell interference effect that occurs when the adjoining memory cell has the C level. The amount of shift from the E level to the A level and the amount of shift from the LM level to the C level become smaller than those in the initial state. Therefore, the value of the reading pass voltage Vdla is set smaller in accordance with the decrease of these amounts of shift. For example, the correction value α is changed from an initial value (600 mV) to a correction value α″ (400 mV) smaller than the initial value. Also in this case, in reading one page, it is possible to share the correction value α″ between when the data in the adjoining memory cell Mn+1 has the A level and when it has the C level. As a result, it is possible to reduce the substantial inter-cell interference effect to 0V without complicating the operation of the control circuit 10, for the number of correction values α does not increase.

The number of times data writing/erasing has been executed is stored in the control circuit 10. When the number of times data writing/erasing has been executed has exceeded a certain number of times, the control circuit 10 raises the LM level in a data writing operation. At the same time, in a reading operation, the control circuit 10 changes from the correction value α to the correction value α″ stored in the ROM area 10-1 and uses the latter to correct the value of the reading pass voltage Vdla. It is also possible to use smaller values as the number of times data writing/erasing has been executed increases. For example, where correction value α>correction value α″>correction value α′″, as the number of times data writing/erasing has been executed increases, the control circuit 10 uses the correction value in the order of correction value α→correction value α″→correction value α′″ to correct the value of the reading pass voltage Vdla. The correction value α″ and the correction value α′″ are also stored in the ROM area 10-1.

When the lower limit of the threshold voltage distribution of the LM level is a negative voltage as shown in FIG. 5, a negative voltage VLM is used in a verify reading operation for the LM level written by the lower page program. However, verify reading for the LM level in a so-called negative sense scheme can be executed without the negative voltage VLM.

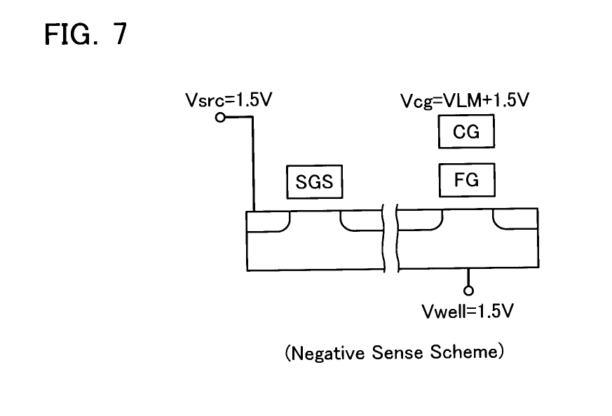

FIG. 7 is a schematic diagram for explaining the negative sense scheme according to the present embodiment. FIG. 7 shows an example where the lower limit of the distribution of the LM level is −1.5V.

In the case of this example, in a verify reading operation for the LM level, the negative sense scheme applies a positive voltage of, for example, approximately 1.5V as voltages Vsrc and Vwell to be applied to the source line CELSRC and the well SW. This makes it possible to realize a verify voltage VLM of substantially −1.5V only by applying a voltage Vcg of 0V to the control gate CG.

As an alternative scheme, it is also possible to apply a negative voltage to the control gate CG. In this case, however, a circuit for generating a negative voltage is disposed in a chip area. That is, the chip area increases.

In terms of this point, employing the negative sense scheme shown in FIG. 7 when the lower limit of the distribution of the LM level is a negative voltage enables to prevent increase of the chip area.

As described above, according to the present embodiment, the LM level (intermediate distribution) is controlled such that an amount of shift of the threshold voltage distribution from the E level to the A level is substantially the same as an amount of shift of the threshold voltage distribution from the LM level to the C level in the upper page program. Due to this, it is possible to reduce the influence of inter-cell interference appropriately in both of the cases where the adjoining memory cell has the A level and where it has the C level. The negative sense scheme becomes unnecessary when the lower limit of the LM level reaches a positive value as a result of raising the lower limit in accordance with increase of the number of times a writing/erasing operation has been executed. That is, the source line CELSRC and the well SW can be set to 0V. As a result, the verify operation can be executed faster.

### Second Embodiment

In the first embodiment, the LM level is set such that an amount of shift of the threshold voltage distribution from the E level to the A level is substantially the same as an amount of shift of the threshold voltage distribution from the LM level to the C level. This makes it possible to appropriately execute data reading by the DLA method in any of the cases where the adjoining memory cell has the A level and where it has the C level. However, if the E level and the LM level shift to the negative direction along with shrinking of the memory cells, an amount of shift of the threshold voltage distribution from the LM level to the B level in the upper page program also increases. As a result, the influence of inter-cell interference becomes unignorable not only when the adjoining memory cell has the A level or the C level but also when it has the B level.

Hence, according to the second embodiment of the present invention, when the adjoining memory cell has other than the A level and the C level, i.e., when it has the E level or the B level, a reading pass voltage Vdla′ (=Vread+α′) (third reading pass voltage), which is higher than the reading pass voltage Vread used in a verify reading operation executed after the lower page program, is supplied to the adjoining memory cell. The reading pass voltage Vdla′ has a value smaller than the reading pass voltage Vdla described above. That is, the correction value α′ is smaller than the correction value α. In this case, it might seem that the number of correction values α increases. However, in the first embodiment of the present invention, the correction value α′ is set to 0V when the adjoining memory cell has the E level or the B level. That is, in the first embodiment of the present invention, when the adjoining memory cell has the E level or the B level, the value of the reading pass voltage Vread is Vread+α′=Vread+0=Vread. That is, also in the second embodiment of the present invention, it is possible to share the correction value α′ between when the adjoining memory cell has the E level and when it has the B level. Like in the first embodiment of the present invention, the control circuit 10 will use two kinds of correction values α for reading one page. The correction value α′ is stored in the ROM area 10-1 and read out by the control circuit 10 in a data reading operation.

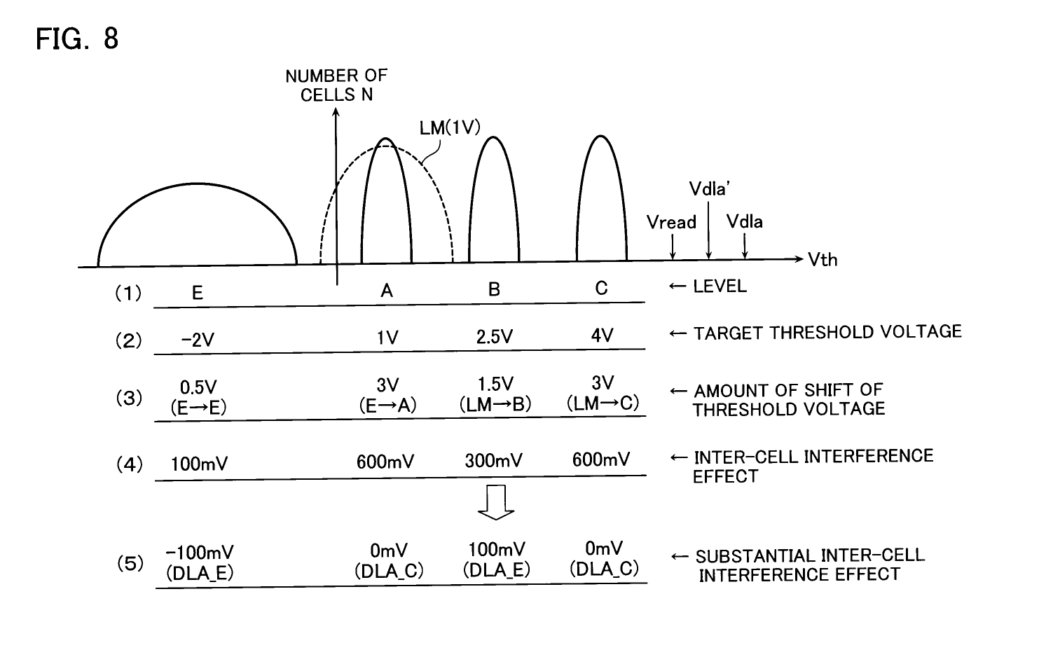

FIG. 8 is a schematic diagram for explaining an inter-cell interference effect in the present embodiment. The target threshold voltages of the E to C levels and of the LM level are the same as in the case shown in FIG. 5.

In this case, like in the case shown in FIG. 5, an inter-cell interference effect that occurs when the adjoining memory cell Mn+1 is shifted from the LM level to the B level causes the threshold voltage distribution of the selected memory cell Mn to shift by 300 mV. Here, if a reading pass voltage Vdla′ enough to cancel this inter-cell interference effect is applied to the control gate of the adjoining memory cell Mn+1, a substantial inter-cell interference effect that occurs when the adjoining memory cell Mn+1 has the B level becomes 0 mV. When the adjoining memory cell Mn+1 has the E level, the same reading pass voltage Vdla′ may also be applied.

Hence, in the present embodiment, the control circuit 10 reads out one-page data by applying any of reading voltages each having a voltage value between adjoining two of the E level to the C level to the word line WLn connected to the reading target memory cells Mn among the plurality of memory cells M while applying the reading pass voltage Vread higher than the upper limit of the threshold of the C level to the word lines WL connected to the non-selected memory cells M.

At this time, when the threshold voltage distribution of the adjoining memory cell that adjoins the selected memory cell Mn is the threshold voltage distribution of the A level or the C level, the control circuit 10 executes first control of applying a voltage Vdla obtained by adding the correction value α to the reading pass voltage Vread to the word line WL connected to the adjoining memory cell.

When the threshold voltage distribution of the adjoining memory cell that adjoins the selected memory cell Mn is the threshold voltage distribution of the E level or the B level, the control circuit 10 executes second control of applying a reading pass voltage Vdla′ obtained by adding the correction value α′ to the reading pass voltage Vread to the word line WL connected to the adjoining memory cell.

Like in the first embodiment, in the present embodiment, it is also preferable to shift the lower limit of the LM level gradually to the positive direction as the number of times a data writing operation/erasing operation has been executed increases. In this case, the amount of shift between the LM level and the B level gradually decreases. Accordingly, in the present embodiment, it is further preferable to lower the value of the voltage Vdla′ gradually as the number of times a writing operation/erasing operation has been executed increases. That is, it is preferable that the control circuit 10 change the correction value α′ to smaller values as the number of times a writing operation/erasing operation has been executed increases.

As described above, according to the present embodiment, it is possible not only to appropriately compensate for inter-cell interference that occurs when the adjoining memory cell has the A level or the C level, but also to substantially reduce an inter-cell interference effect that occurs when the threshold voltage is the B level.

### OTHERS

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a memory cell array configured as an array of a plurality of memory strings each including a plurality of memory cells connected in series, each of the memory cells being caused to store first to fourth data by being provided with a first threshold voltage distribution, a second threshold voltage distribution having a voltage value higher than that of the first threshold voltage distribution, a third threshold voltage distribution having a voltage value higher than that of the second threshold voltage distribution, or a fourth threshold voltage distribution having a voltage value higher than that of the third threshold voltage distribution; and
a control circuit configured to be able to execute first page writing to shift a threshold voltage of the memory cell from the first threshold voltage distribution to an intermediate distribution, and second page writing to shift a threshold voltage of the memory cell from the first threshold voltage distribution to the second threshold voltage distribution or from the intermediate distribution to the third or fourth threshold voltage distribution, and configured to be able to execute reading of data from a reading target, which is a first memory cell among the plurality of memory cells, by applying to the first memory cell any one of reading voltages each having a voltage value between adjoining two of the first to fourth threshold voltage distributions, while applying a first reading pass voltage higher than an upper limit of the fourth threshold voltage distribution to other memory cells,
the control circuit being configured to set a lower limit of the intermediate distribution in the first page writing such that an amount of shift from the first threshold voltage distribution to the second threshold voltage distribution is substantially equal to an amount of shift from the intermediate distribution to the fourth threshold voltage distribution, and to execute control of raising the lower limit of the intermediate distribution as the number of times the writing or erasing has been executed increases,
the control circuit being configured to, when a threshold voltage distribution of a second memory cell adjoining the first memory cell and subject to data write after the first memory cell is the second or fourth threshold voltage distribution, execute control of applying a second reading pass voltage higher than the first reading pass voltage to the second memory cell.

2. The nonvolatile semiconductor memory device according to claim 1,
wherein when the threshold voltage distribution of the second memory cell is the third threshold voltage distribution, the control circuit executes control of applying a third reading pass voltage lower than the second reading pass voltage and higher than the first reading pass voltage to the second memory cell.

3. The nonvolatile semiconductor memory device according to claim 1,
wherein the memory string is connected to a source line via a select transistor, and
when the lower limit of the intermediate distribution is a negative voltage, the control circuit applies a positive voltage to a semiconductor layer having the memory cell disposed therein and to the source line.

4. The nonvolatile semiconductor memory device according to claim 1,
wherein the second reading pass voltage is generated by the control circuit adding a correction value to the first reading pass voltage.

5. The nonvolatile semiconductor memory device according to claim 2,
wherein the third reading pass voltage is lowered as the number of times the writing or erasing has been executed increases.

6. The nonvolatile semiconductor memory device according to claim 4, comprising a memory area having the correction value stored therein.

7. The nonvolatile semiconductor memory device according to claim 6,
wherein the memory area stores a plurality of correction values having different levels, and
the control circuit generates the second reading pass voltage by acquiring a lower one of the correction values as the number of times the writing or erasing has been executed increases.

8. The nonvolatile semiconductor memory device according to claim 1,
wherein before the first page writing, the control circuit executes a soft program of adjusting a lower limit of the first threshold voltage distribution to a certain voltage value.

9. A nonvolatile semiconductor memory device, comprising:
a memory cell array configured as an array of a plurality of memory strings each including a plurality of memory cells connected in series, each of the memory cells being caused to store first to fourth data by being provided with a first threshold voltage distribution, a second threshold voltage distribution having a voltage value higher than that of the first threshold voltage distribution, a third threshold voltage distribution having a voltage value higher than that of the second threshold voltage distribution, or a fourth threshold voltage distribution having a voltage value higher than that of the third threshold voltage distribution; and
a control circuit configured to be able to execute first page writing to shift a threshold voltage of the memory cell from the first threshold voltage distribution to an intermediate distribution, and second page writing to shift a threshold voltage of the memory cell from the first threshold voltage distribution to the second threshold voltage distribution or from the intermediate distribution to the third or fourth threshold voltage distribution, and configured to be able to execute reading of data from a reading target, which is a first memory cell among the plurality of memory cells, by applying to the first memory cell any one of reading voltages each having a voltage value between adjoining two of the first to fourth threshold voltage distributions, while applying a first reading pass voltage higher than an upper limit of the fourth threshold voltage distribution to other memory cells,
the control circuit being configured to set a lower limit of the intermediate distribution in the first page writing such that an amount of shift from the first threshold voltage distribution to the second threshold voltage distribution is substantially equal to an amount of shift from the intermediate distribution to the fourth threshold voltage distribution,
the control circuit being configured to, when a threshold voltage distribution of a second memory cell adjoining the first memory cell and subject to data write after the first memory cell is the second or fourth threshold voltage distribution, execute control of applying a second reading pass voltage higher than the first reading pass voltage to the second memory cell.

10. The nonvolatile semiconductor memory device according to claim 9,
wherein when the threshold voltage distribution of the second memory cell is the third threshold voltage distribution, the control circuit executes control of applying a third reading pass voltage lower than the second reading pass voltage and higher than the first reading pass voltage to the second memory cell.

11. The nonvolatile semiconductor memory device according to claim 9,
wherein the memory string is connected to a source line via a select transistor, and
when the lower limit of the intermediate distribution is a negative voltage, the control circuit applies a positive voltage to a semiconductor layer having the memory cell disposed therein and to the source line.

12. The nonvolatile semiconductor memory device according to claim 9,
wherein the second reading pass voltage is generated by the control circuit adding a correction value to the first reading pass voltage.

13. The nonvolatile semiconductor memory device according to claim 12, comprising a memory area having the correction value stored therein.

14. The nonvolatile semiconductor memory device according to claim 9,
wherein before the first page writing, the control circuit executes a soft program of adjusting a lower limit of the first threshold voltage distribution to a certain voltage value.

15. A method of controlling a nonvolatile semiconductor memory device,
the nonvolatile semiconductor memory device comprising a memory cell array configured as an array of a plurality of memory strings each including a plurality of memory cells connected in series, each of the memory cells being caused to store first to fourth data by being provided with a first threshold voltage distribution, a second threshold voltage distribution having a voltage value higher than that of the first threshold voltage distribution, a third threshold voltage distribution having a voltage value higher than that of the second threshold voltage distribution, or a fourth threshold voltage distribution having a voltage value higher than that of the third threshold voltage distribution,
in a data writing operation, the method comprising:
executing first page wiring to shift a threshold voltage of the memory cell from the first threshold voltage distribution to an intermediate distribution;
executing second page writing to shift the threshold voltage of the memory cell from the first threshold voltage distribution to the second threshold voltage distribution, or from the intermediate distribution to the third or fourth threshold voltage distribution to set a lower limit of the intermediate distribution in the first page writing such that an amount of shift from the first threshold voltage distribution to the second threshold voltage distribution is substantially equal to an amount of shift from the intermediate distribution to the fourth threshold voltage distribution, and
in a data reading operation, the method comprising:
applying to a reading target first memory cell among the plurality of memory cells any one of reading voltages each having a voltage value between adjoining two of the first to fourth threshold voltage distributions, and applying a first reading pass voltage higher than an upper limit of the fourth threshold voltage distribution to other memory cells; and
when a threshold voltage distribution of a second memory cell adjoining the first memory cell and having data written thereinto after the first memory cell is the second or fourth threshold voltage distribution, applying a second reading pass voltage higher than the first reading pass voltage to the second memory cell.

16. The method of controlling the nonvolatile semiconductor memory device according to claim 15, comprising raising the lower limit of the intermediate distribution as the number of times the writing of data or erasing of data has been executed increases.

17. The method of controlling the nonvolatile semiconductor memory device according to claim 15, comprising applying a third reading pass voltage lower than the second reading pass voltage and higher than the first reading pass voltage to the second memory cell, when the threshold voltage distribution of the second memory cell is the third threshold voltage distribution.

18. The method of controlling the nonvolatile semiconductor memory device according to claim 15,
wherein the memory string is connected to a source line via a select transistor, and
the method comprises applying a positive voltage to a semiconductor layer having the memory cell formed therein and to the source line, when the lower limit of the intermediate distribution is a negative voltage.

19. The method of controlling the nonvolatile semiconductor memory device according to claim 15, comprising generating the second reading pass voltage by adding a correction value to the first reading pass voltage.

20. The method of controlling the nonvolatile semiconductor memory device according to claim 15, comprising executing, before the first page writing, a soft program of adjusting a lower limit of the first threshold voltage distribution to a certain voltage value.
